(19) United States
(12) Patent Application Publication
(10) Pub. No.: US 2021/0395488 A1
(43) Pub. Date: Dec. 23, 2021

(54) CYCLIC PHOSPHAZENE COMPOUND, FLAME RETARDANT FOR RESIN, RESIN COMPOSITION INCLUDING SAME, AND MOLDING OF SAID RESIN COMPOSITION

(71) Applicant: OTSUKA CHEMICAL CO., LTD., Osaka-shi, Osaka (JP)

(72) Inventors: Junji NANTAKU, Tokushima-shi (JP); Masaki MURAKAMI, Tokushima-shi (JP)

(73) Assignee: OTSUKA CHEMICAL CO., LTD., Osaka-shi, Osaka (JP)

(21) Appl. No.: 17/283,484

(22) PCT Filed: Oct. 9, 2019
(86) PCT No.: PCT/JP2019/039796

§ 371 Date: Jun. 2, 2021

(30) Foreign Application Priority Data
Oct. 9, 2018 (JP) 2018-190779

(51) Int. Cl. C08K 5/5399; C07F 9/6581; C09K 21/12

(52) U.S. Cl. CPC C08K 5/5399; H01L 23/293; C09K 21/12; C07F 9/65818

(57) ABSTRACT

The resin composition according to the present invention and a molded article of the composition contain a resin and a cyclic phosphazene compound represented by formula (1). A resin composition that has high flame retardancy while maintaining resin-derived mechanical strength, and a molded article of the composition are provided by using this configuration.

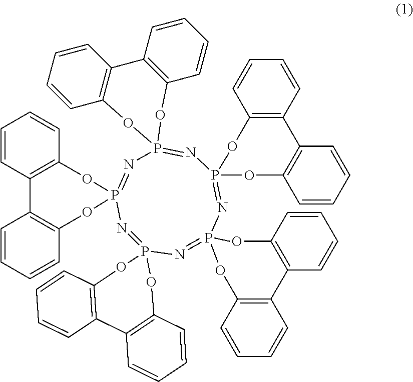 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

### TECHNICAL FIELD

The present invention relates to a cyclic phosphazene compound, a flame retardant for resin, a resin composition containing the cyclic phosphazene compound or the flame retardant for resin, and a molded article of the resin composition.

### BACKGROUND ART

Resin-molded articles, which are lightweight and can be excellent in electrical insulation, thermal insulation, chemical resistance, mechanical strength, and other properties, depending on the type of resin, have applications in many fields such as electrical and electronic components, and automotive components. However, many resin-molded articles are combustible and strictly required to be fire-resistant from the disaster prevention perspective.

To solve this problem, a flame retardant is usually added to resin. A higher amount of a flame retardant added to resin enables the resin-molded article to exhibit higher flame retardancy.

However, a large amount of a flame retardant added to resin may reduce the mechanical strength of the resin-molded article. Thus, there is demand for a technique to enable a resin-molded article to exhibit high flame retardancy while maintaining resin-derived mechanical strength.

There are techniques to enable a resin-molded article to exhibit high flame retardancy while maintaining resin-derived mechanical strength, such as a technique to add a filler, a halogen-based flame retardant, a flame retardant aid, and a polytetrafluoroethylene resin to a polypropylene resin composition (PTL 1); a technique to add a non-halogen-based flame retardant, a polyhydroxy polyurethane resin, and a silicon compound to a polyurethane resin composition (PTL 2); and a technique to add a phosphorus-containing epoxy resin to a polyester resin composition (PTL 3).

### CITATION LIST

### Patent Literature

### PTL 1: JP2015-078277A

### PTL 2: JP2016-030798A

### PTL 3: JP2001-114996A

### SUMMARY OF INVENTION

### Technical Problem

The techniques disclosed in PTL 1 to 3 have restrictions that specific resins or specific components other than resins and flame retardants must be used, and may significantly change the physical properties of resin-molded articles. Thus, these techniques are not useful.

An object of the present invention is to provide a resin composition that has high flame retardancy while maintaining resin-derived mechanical strength, and a molded article of the resin composition.

### Solution to Problem

The present inventors conducted research and found that a molded article prepared from a resin composition that contains a resin and a cyclic phosphazene compound represented by formula (1) has high flame retardancy while maintaining resin-derived mechanical strength. The inventors then completed the present invention.

Specifically, the present invention encompasses the cyclic phosphazene compound, the flame retardant for resin, the resin composition containing the cyclic phosphazene compound or the flame retardant for resin, and the molded article of these described in the following Items 1 to 12.

### Item 1.

A cyclic phosphazene compound represented by formula (1).

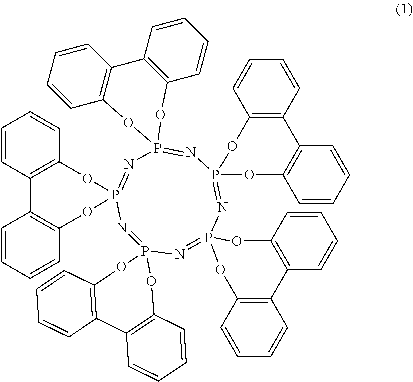 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

### Item 2.

A resin composition comprising a resin and a cyclic phosphazene compound represented by formula (1).

### Item 3.

The resin composition according to Item 2, wherein the cyclic phosphazene compound is present in an amount of 0.01 to 50 parts by mass, per 100 parts by mass of the resin.

### Item 4.

The resin composition according to Item 2 or 3, wherein the resin is at least one member selected from the group consisting of epoxy resin, thermosetting acrylic resin, diallyl phthalate resin, unsaturated polyester resin, styrene-based resin, polyester resin, polycarbonate resin, polyphenylene ether-based resin, and polyamide resin.

### Item 5.

A molded article prepared by using the resin composition of any one of Items 2 to 4.

### Item 6.

An electric or electronic component prepared by using the resin composition of any one of Items 2 to 4.

### Item 7.

A sealing material for a semiconductor device, the sealing material comprising the resin composition of any one of Items 2 to 4.

### Item 8.

A substrate material prepared by using the resin composition of any one of Items 2 to 4.

### Item 9.

A method for producing a cyclic phosphazene compound represented by formula (1)

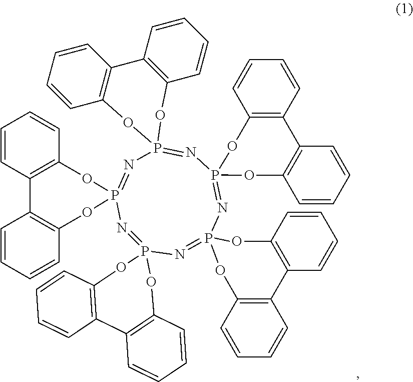 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

the method comprising reacting decachlorocyclopentaphosphazene with 2,2′-biphenolate.

### Item 10.

A flame retardant for resin, the flame retardant comprising a cyclic phosphazene compound represented by formula (1).

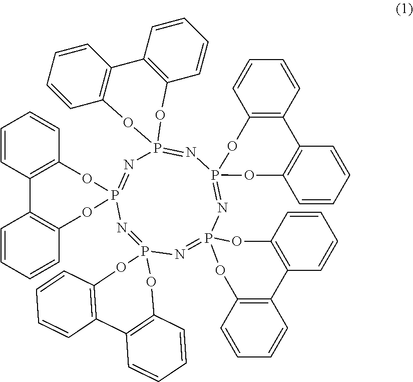 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

### Item 11.

A resin composition comprising a resin and the flame retardant for resin of Item 10.

### Item 12.

The resin composition according to Item 11, comprising the flame retardant for resin in an amount of 0.01 to 50 parts by mass, per 100 parts by mass of the resin.

### Advantageous Effects of Invention

Because the resin composition according to the present invention contains a cyclic phosphazene compound represented by formula (1), a molded article prepared from the resin composition exhibits high flame retardancy while maintaining resin-derived mechanical strength. The resin composition according to the present invention is also advantageous in that the resin composition does not significantly change the properties of the resulting molded article due to not having restrictions by components other than the resin and cyclic phosphazene compound represented by formula (1). Therefore, the molded article according to the present invention can be suitably used particularly in electric or electronic components.

### DESCRIPTION OF EMBODIMENTS

The present invention is described in detail below.

In the present specification, “comprise,” “contain,” and “include” include all the concepts of comprising, consisting essentially of, and consisting of. In the present specification, a numerical range expressed by “A to B” indicates “A or more and B or less” unless otherwise specified.

### Cyclic Phosphazene Compound Represented by Formula (1)

The cyclic phosphazene compound according to the present invention is represented by formula (1).

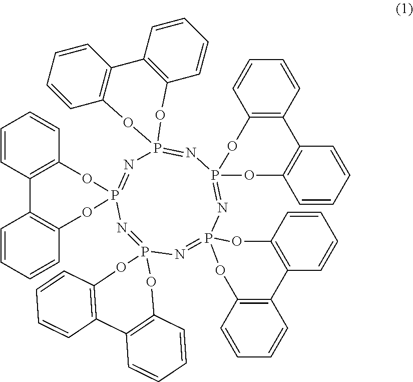 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

The compound represented by formula (1) (“compound (1)” below) can be produced by reacting decachlorocyclopentaphosphazene represented by formula (2) (“compound (2)” below) with 2,2′-biphenolate.

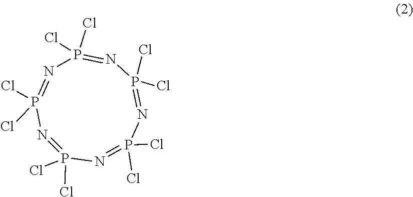 [SMILES: ClP1(Cl)=NP(Cl)(Cl)=NP(Cl)(Cl)=NP(Cl)(Cl)=NP(Cl)(Cl)=N1]

The amount of 2,2′-biphenolate for use is preferably 5 to 7.5 mol, and more preferably 5.3 to 5.8 mol, per mol of compound (2).

This reaction is preferably performed in a solvent. Examples of solvents include halogen-based solvents, such as monochlorobenzene, o-dichlorobenzene, m-dichlorobenzene, dichloromethane, 1,2-dichloroethane, 1,1-dichloroethane, and sym-tetrachloroethane; aliphatic hydrocarbon-based solvents, such as n-pentane and n-hexane; aromatic hydrocarbon-based solvents, such as benzene, toluene, o-xylene, and m-xylene; carbonate-based solvents, such as dimethyl carbonate, diethyl carbonate, and propylene carbonate; ether-based solvents, such as diethyl ether, methyl ethyl ether, cyclopentyl methyl ether, triethylene glycol dimethyl ether, 1,4-dioxane, 1,3-dioxane, and tetrahydrofuran; nitrile-based solvents, such as acetonitrile, butyronitrile, and benzonitrile; nitro compound-based solvents, such as nitromethane and nitrobenzene; ketone-based solvents, such as acetone, methyl isobutyl ketone, cyclopentanone, and cyclohexanone; and ester-based solvents, such as ethyl acetate, methyl propionate, and ethyl propionate. Of these, halogen-based solvents are preferable. Monochlorobenzene, o-dichlorobenzene, and m-dichlorobenzene are more preferable. Monochlorobenzene is particularly preferable. The amount of a solvent for use is preferably 1 to 20 parts by mass, and more preferably 1.5 to 15 parts by mass, per part by mass of compound (2).

The reaction temperature is preferably about 20 to 140° C., and more preferably 25 to 135° C.

The reaction time is preferably about 0.5 to 20 hours, and more preferably 1 to 12 hours.

Compound (2) can be produced by preparing a cyclic chlorophosphazene oligomer represented by formula (3) in accordance with a known method described in, for example, JPS57-3705 or JPS57-77012 and then performing an isolation operation such as distillation. Compound (2) is a compound represented by formula (3) wherein m is 5.

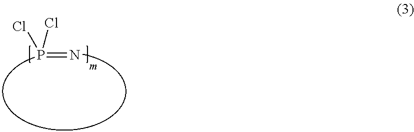

wherein m represents an integer of 3 to 15.

2,2′-Biphenolate may be a commercially available product or 2,2′-biphenolate prepared by a known method.

An example of methods for producing 2,2′-biphenolate is reacting 2,2′-biphenol with a base in the presence or absence of a solvent.

Examples of bases include alkali metal salts and amine compounds. Alkali metal salts, such as lithium hydroxide, sodium hydroxide, potassium hydroxide, lithium carbonate, sodium carbonate, and potassium carbonate, are preferable. The amount of a base for use is preferably 1.8 to 4 mol, and more preferably 2 to 3 mol, per mol of 2,2′-biphenol.

The solvent for use can be any solvent that does not affect the reaction. Such solvents are as described above for the production reaction for compound (1).

After completion of the reaction, the reaction mixture is subjected to a known isolation operation, such as extraction and washing, to obtain 2,2′-biphenolate. Alternatively, without isolating 2,2′-biphenolate, the reaction mixture may be reacted with compound (2).

As described above, compound (1) can be produced by the method of directly reacting commercially available 2,2′-biphenolate or 2,2′-biphenolate synthesized by the method described above with compound (2). Alternatively, compound (1) can be produced by a method of reacting 2,2′-biphenol, a base, and compound (2) in a single system to prepare 2,2′-biphenolate in the reaction system, and reacting 2,2′-biphenolate with compound (2).

In this case, the amount of 2,2′-biphenol for use is preferably 5 to 7.5 mol, and more preferably 5.3 to 5.8 mol, per mol of compound (2). The amount a base for use is preferably 9 to 20 mol, and more preferably 10 to 12 mol, per mol of compound (2).

Examples of usable solvents in this method include those listed above for the method of directly reacting 2,2′-biphenolate with compound (2). Of these, ether-based solvents and ketone-based solvents are preferable, and tetrahydrofuran and acetone are particularly preferable. The amount of the solvent for use is preferably 1 to 20 parts by mass, and more preferably 1.5 to 15 parts by mass, per part by mass of compound (2).

The reaction temperature and reaction time for this method are as described for the method of directly reacting 2,2′-biphenolate with compound (2).

The method for producing compound (1) is preferably the method of directly reacting 2,2′-biphenolate with compound (2).

The obtained compound (1) can be purified by a known purification method. Examples of purification methods include column chromatography and extraction.

Compound (1) can also be produced by reacting 2,2′-biphenolate with the cyclic chlorophosphazene oligomer represented by formula (3) instead of compound (2) in the same manner above, and isolating the reaction product by a purification method such as chromatography.

### Flame Retardant for Resin

The flame retardant for resin according to the present invention contains the cyclic phosphazene compound represented by formula (1). Examples of resins to which the flame retardant is applied include epoxy resin, thermosetting acrylic resin, diallyl phthalate resin, unsaturated polyester resin, styrene-based resin, polyester resin, polycarbonate resin, polyphenylene ether-based resin, and polyamide resin.

The flame retardant for resin according to the present invention may also contain other flame retardants in addition to the cyclic phosphazene compound represented by formula (1). Examples of other flame retardants include hexaphenoxy cyclotriphosphazene, hexa(p-hydroxyphenoxy) cyclotriphosphazene, tetraaminodiphenoxy cyclotriphosphazene, tris (o-allylphenoxy)-tris(phenoxy) cyclotriphosphazene, tridioxybiphenyl cyclotriphosphazene, tetradioxybiphenyl cyclotetraphosphazene, anilinodiphenyl phosphate, di-o-cresylphenylamino phosphate, cyclohexylaminodiphenyl phosphate, phosphoramide acid-1,4-phenylene bis-tetrakis (2,6-dimethylphenyl) ester, monoammonium phosphate, diammonium phosphate, triammonium phosphate, ammonium polyphosphate, melanin polyphosphate, resorcinol poly(di-2,6-xylyl) phosphate, and resorcinol polyphenyl phosphate. The flame retardant for resin according to the present invention may also contain a cyclic phosphazene oligomer represented by formula (4) (n being 6 or more, and preferably 6 to 15).

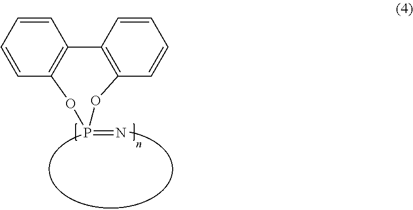

wherein n represents an integer of 6 or more.

The flame retardant for resin according to the present invention may contain other additives that can be added to the resin composition, described below.

### Resin Composition

The resin composition according to the present invention contains a resin and the cyclic phosphazene compound represented by formula (1).

As described above, because the flame retardant for resin according to the present invention contains the cyclic phosphazene compound represented by formula (1), the resin composition according to the present invention also encompasses the embodiment in which the resin composition contains the flame retardant for resin.

The resin that constitutes the resin composition according to the present invention can be any resin, and may be a resin obtained by a known method or a commercially available product. Specifically, examples include thermosetting resins and thermoplastic resins. In the present invention, rubber and elastomer are included in “resin.” A thermosetting resin and a thermoplastic resin may also be used in combination.

Examples of thermosetting resins include epoxy resin, phenol resin, melamine resin, urea resin, silicone resin, polyurethane resin, unsaturated polyester resin, diallyl phthalate resin, thermosetting acrylic resin, thermosetting polyimide resin, polycarbodiimide resin, natural rubber, isoprene rubber, styrene butadiene rubber, butadiene rubber, butyl rubber, ethylene propylene diene rubber, acrylonitrile butadiene rubber, styrene isoprene butadiene rubber, and chloroprene rubber. Of these, one member can be used, or a combination of two or more members can also be used.

Examples of thermoplastic resins include polyolefin resins (e.g., polyethylene resin, polypropylene resin, polyisoprene resin, polybutylene resin, cyclic polyolefin (COP) resin, and cyclic olefin copolymer (COC) resin), chlorinated polyolefin resins (e.g., polyvinylchloride resin and polyvinylidene chloride), styrene-based resins (polystyrene resin, high impact polystyrene (HIPS) resin, syndiotactic polystyrene (SPS) resin, acrylonitrile-butadiene-styrene copolymers (ABS resin), acrylonitrile-styrene copolymers (AS resin), methyl methacrylate-butadiene-styrene copolymers (MBS resin), methyl methacrylate-acrylonitrile-butadiene-styrene copolymers (MABS resin), acrylonitrile-acrylic rubber-styrene copolymers (AAS resin)), polymethyl methacrylate (PMMA), polyvinyl alcohol, polyester resins (e.g., polyethylene terephthalate resin, polybutylene terephthalate resin, polymethylene terephthalate resin, polyethylene naphthalate resin, polycyclohexylene dimethylene terephthalate resin, and polylactic acid resin), aliphatic polyamide resins (e.g., polyamide 6 resin, polyamide 66 resin, polyamide 11 resin, polyamide 12 resin, polyamide 46 resin, copolymers of polyamide 6 resin and polyamide 66 resin (polyamide 6/66 resin), and copolymers of polyamide 6 resin and polyamide 12 resin (polyamide 6/12 resin)), semi-aromatic polyamide resins (resins composed of an aromatic ring-containing structural unit and an aromatic ring-free structural unit, such as polyamide MXD6 resin, polyamide 6T resin, polyamide 9T resin, and polyamide 10T resin), polyacetal (POM) resin, polycarbonate resin, phenoxy resin, polyphenylene ether-based resin, polysulfone-based resin, polyether sulfone resin, polyphenylene sulfide resin, polyether nitrile resin, polythioether sulfone resin, polyarylate resin, polyamide-imide resin, polyether-imide resin, aromatic polyetherketone resin (e.g., polyether ketone resin, polyether ketone ketone resin, polyether ether ketone ketone resin, and polyether ether ketone resin), thermoplastic polyimide (TPI) resin, liquid crystal polymer (LCP) resin (e.g., liquid crystal polyester resin), polyamide-based thermoplastic elastomers, polyester-based thermoplastic elastomers, and polybenzimidazole resins. Of these, one member can be used, or a combination of two or more members can be used.

Of these, at least one member or two or more members selected from epoxy resin, thermosetting acrylic resin, diallyl phthalate resin, unsaturated polyester resin, styrene-based resin, polyester resin, polycarbonate resin, polyphenylene ether-based resin, and polyamide resin are preferable. Of these, epoxy resin is particularly preferable.

In the present specification, “epoxy resin” refers to a reaction product of an epoxy compound with a curing agent.

Examples of epoxy compounds include novolac-type epoxy compounds obtained by reacting a reaction product of a phenol with formaldehyde with an epichlorohydrin such as epichlorohydrin or 2-methyl epichlorohydrin; phenolic epoxy compounds obtained by reacting a phenol with an epichlorohydrin; aliphatic epoxy compounds obtained reacting an alcohol such as trimethylolpropane, oligopropylene glycol, or hydrogenated bisphenol-A with an epichlorohydrin; glycidyl ester-based epoxy compounds obtained by reacting hexahydrophthalic acid, tetrahydrophthalic acid, or phthalic acid with an epichlorohydrin; glycidyl amine-based epoxy compounds obtained by reacting an amine such as diaminodiphenyl methane or aminophenol with an epichlorohydrin; and heterocyclic epoxy compounds obtained by reacting a polyamine such as isocyanuric acid with an epichlorohydrin.

Novolac-type epoxy compounds include phenol novolac-type epoxy compounds, brominated phenol novolac-type epoxy compounds, o-cresol novolac-type epoxy compounds, and naphthol novolac-type epoxy compounds.

Phenolic epoxy compounds include bisphenol A-type epoxy compounds, brominated bisphenol A-type epoxy compounds, bisphenol F-type epoxy compounds, bisphenol AD-type epoxy compounds, bisphenol S-type epoxy compounds, alkyl-substituted biphenolic epoxy compounds, and tris (hydroxyphenyl)methane-type epoxy compounds.

Of these, phenol novolac-type epoxy compounds, o-cresol novolac-type epoxy compounds, bisphenol A-type epoxy compounds, and bisphenol F-type epoxy compounds are preferable. These compounds can be used singly, or in a combination of two or more. An epoxy resin can be produced in the composition. For example, an epoxy resin can be obtained by adding an epoxy compound and a curing agent to the composition, and heating the mixture to form it into a resin.

Additionally, epoxy resin can be modified by adding a monofunctional epoxy compound or a polyfunctional epoxy compound to the epoxy compounds described above.

Specific examples of monofunctional epoxy compounds include butyl glycidyl ether, phenyl glycidyl ether, cresyl glycidyl ether, allyl glycidyl ether, and glycidyl ether of an alcohol.

Polyfunctional epoxy compounds include bifunctional epoxy compounds and trifunctional or higher functional epoxy compounds.

Specific examples of bifunctional epoxy compounds include ethylene glycol diglycidyl ether, propylene glycol diglycidyl ether, tripropylene glycol diglycidyl ether, 1,6-hexanediol diglycidyl ether, diglycidyl ether of bisphenol A, butadiene diepoxide, 3,4-epoxycyclohexylmethyl-(3,4-epoxy) cyclohexane carboxylate, vinylcyclohexane dioxide, 4,4′-di(1,2-epoxyethyl) diphenyl ether, 4,4′-(1,2-epoxyethyl) biphenyl, 2,2-bis(3,4-epoxycyclohexyl)propane, glycidyl ether of resorcinol, diglycidyl ether of phloroglucin, diglycidyl ether of methyl phloroglucin, bis(2,3′-epoxycyclopentyl)ether, 2-(3,4-epoxy) cyclohexane-5,5-spiro (3,4-epoxy) cyclohexane-m-dioxane, bis (3,4-epoxy-6-methylcyclohexyl)adipate, and N,N′-m-phenylene bis(4,5-epoxy-1,2-cyclohexane) dicarboximide.

Specific examples of trifunctional or higher functional epoxy compounds include triglycidyl ether of p-aminophenol, polyallyl glycidyl ether, 1,3,5-tri (1,2-epoxyethyl)benzene, 2,2′,4,4′-tetraglycidoxy benzophenone, polyglycidyl ether of phenol formaldehyde novolac, triglycidyl ether of trimethylolpropane, and triglycidyl ether of trimethylolpropane.

These monofunctional epoxy compounds or polyfunctional epoxy compounds can be used singly, or in a combination of two or more.

The curing agent for use can be selected from a wide range of curing agents known in the art. Examples of curing agents include dicyandiamide (DICY) compounds, novolac-type phenol resin, amino-modified novolac-type phenol resin, polyvinyl phenol resin, organic acid hydrazide, diaminomaleonitrile compounds, melamine compounds, amineimides, polyamine salts, molecular sieves, amine compounds (e.g., diaminodiphenyl sulfone, m-xylylenediamine, N-aminoethylpiperazine, and diethylenetriamine), acid anhydrides, polyamides, imidazoles, and light or UV curing agents.

These curing agents can be used singly, or in a combination of two or more.

The amount of the curing agent for use can be suitably adjusted in accordance with, for example, the epoxy equivalent of the epoxy compound or the active hydrogen equivalent or amine equivalent of the curing agent (active hydrogen equivalent of an amine-based curing agent) based on the number of functional groups of the epoxy compound and the curing agent.

Additionally, a curing aide may be added to facilitate the curing process. The curing aid for use can be selected from a wide range of curing aides known in the art. Examples of curing aides include tertiary amines, imidazoles, aromatic amines, and triphenylphosphine. These curing aids can be used singly, or in a combination of two or more. The amount of the curing aid for use can be any amount, and is typically 10 parts by mass or less, and preferably 5 parts by mass or less, per 100 parts by mass of the epoxy resin.

The resin composition according to the present invention may contain the cyclic phosphazene compound represented by formula (1) in an amount of typically about 0.01 to 50 parts by mass, preferably about 0.5 to 40 parts by mass, more preferably about 1.5 to 35 parts by mass, and particularly preferably about 10 to 30 parts by mass, per 100 parts by mass of the resin.

The resin composition according to the present invention may contain the flame retardant for resin in an amount of typically about 0.01 to 50 parts by mass, preferably about 0.5 to 40 parts by mass, more preferably about 1.5 to 35 parts by mass, and particularly preferably about 10 to 30 parts by mass, per 100 parts by mass of the resin.

The resin composition according to the present invention may optionally contain, for example, a fluorine resin and an inorganic filler in order to further increase flame retardant performance, in particular dripping (fire spread caused by dripping during combustion) prevention performance. One of these components may be added, or both may be added simultaneously.

The fluorine resin for use can be a known fluorine resin. Examples of fluorine resins include polytetrafluoroethylene (PTFE), tetrafluoroethylene-hexafluoropropylene copolymers (FEP), tetrafluoroethylene-perfluoroalkyl vinyl ether copolymers (PFA), tetrafluoroethylene-ethylene copolymers (ETFE), poly(trifluorochloroethylene) (CTFE), and polyfluorovinylidene (PVdF). Of these, PTFE is preferable. These fluorine resins may be used singly, or in a combination of two or more.

The amount of the fluorine resin for use can be any amount, and is typically, about 0.01 to 2.5 parts by mass, and preferably about 0.1 to 1.2 parts by mass, per 100 parts by mass of the resin.

The inorganic filler can increase not only a dripping prevention effect, but also mechanical strength, electric performance (e.g., insulation, conductivity, anisotropic conductivity, dielectric properties, and moisture resistance), thermal performance (e.g., heat resistance, solder heat resistance, heat conductance, low heat shrinkage, low heat expansion, low stress, thermal shock resistance, heat cycle resistance, reflow crack resistance, storage stability, and temperature cycle resistance), and workability or moldability (e.g., fluidity, curability, adhesiveness, tackiness, pressure adhesiveness, adhesion, underfilling properties, void-free properties, wear resistance, lubricity, releasability, high elasticity, low elasticity, flexibility, and bendability) of the resin composition.

The inorganic filler for use can be any inorganic filler and can be selected from known inorganic fillers. Examples of inorganic fillers include mica, kaolin, talc, molten silica, crystalline silica, alumina, clay, barium sulfate, barium carbonate, calcium carbonate, calcium sulfate, aluminum hydroxide, magnesium hydroxide, calcium silicate, titanium oxide, zinc oxide, zinc borate, aluminum nitride, boron nitride, silicon nitride, glass beads, glass balloons, glass flakes, glass fibers, fibrous alkali metal titanate (e.g., potassium titanate fiber and sodium titanate fiber), fibrous borate (e.g., aluminum borate fiber, magnesium borate fiber, zinc borate fiber), zinc oxide fiber, titanium oxide fiber, magnesium oxide fiber, gypsum fiber, aluminum silicate fiber, calcium silicate fiber, silicon carbide fiber, titanium carbide fiber, silicon nitride fiber, titanium nitride fiber, carbon fiber, silicon carbide fiber, alumina fiber, alumina-silica fiber, zirconia fiber, quartz fiber, flaky titanate, and flaky titanium oxide.

Of these, from the standpoint of increasing mechanical strength, inorganic fillers having shape anisotropy, such as fibrous materials and flaky or plate-like materials, are preferable; fibrous alkali metal titanate, wollastonite fiber, zonotrite fiber, basic magnesium sulfate fiber, fibrous borate, zinc oxide fiber, calcium silicate fiber, flaky titanate, flaky titanium oxide, mica, mica, sericite, illite, talc, kaolinite, montmorillonite, boehmite, smectite, vermiculite, and like materials are particularly preferable. From the standpoint of increasing, for example, electric performance, thermal performance, and workability or moldability, spherical or powdery inorganic fillers, such as molten silica, crystalline silica, alumina, talc, aluminum nitride, boron nitride, silicon nitride, titanium oxide, and barium sulfate, are preferable; and spherical or powdery inorganic fillers, such as molten silica, crystalline silica, alumina, and aluminum nitride, are particularly preferable.

These inorganic fillers can be used singly, or in a combination of two or more.

For the purpose of reducing the degradation of the resin component, inorganic fillers whose surface is coated with a surface treatment agent, such as a silane coupling agent or a titanium coupling agent, are also usable.

The amount of the inorganic filler for use is typically about 0.01 to 90 parts by mass, and preferably about 1 to 80 parts by mass, per 100 parts by mass of the resin.

The resin composition according to the present invention may contain other additives to the extent that the preferable properties of the composition are not impaired. Other additives include a variety of flame retardants. The flame retardants can be any flame retardants. Examples include inorganic flame retardants, halogen-based flame retardants, and phosphorus-based flame retardants. Specific examples include aluminum hydroxide, magnesium hydroxide, antimony trioxide, antimony pentoxide, tetrabromobisphenol A epoxy oligomers, tetrabromobisphenol A epoxy polymers, tetrabromobisphenol A, tetrabromobisphenol A derivatives, tetrabromobisphenol A polycarbonate, tetrabromobisphenol A carbonate oligomers, tribromobisphenol A bis (dibromopropylether), tribromobisphenol A bis (arylether), bis (pentabromophenyl) ethane, 1,2-bis (2,4,6-)tribromophenoxy) ethane, 2,4,6-tris (2,4,6-tribromophenoxy) triazine, dibromophenol novolac, decabromodiphenyl ether, brominated polystyrene, brominated styrene compounds, ethylenebistetrabromophthalimide, hexabromocyclododecane, hexabromobenzene, pentabromobenzyl acrylate, pentabromobenzyl acrylate polymers, hexaphenoxycyclotriphosphazene, hexa(p-hydroxyphenoxy) cyclotriphosphazene, tetraaminodiphenoxycyclotriphosphazene, tris (o-allylphenoxy)-tris (phenoxy) cyclotriphosphazene, tridioxybiphenylcyclotriphosphazene, tetradioxybiphenylcyclotetraphosphazene, the cyclic phosphazene oligomer represented by formula (4), anilinodiphenyl phosphate, di-o-credylphenylamino phosphate, cyclohexylaminodiphenyl phosphate, phosphoramic acid-1,4-phenylenebis-tetrakis (2,6-dimethylphenyl) ester, monoammonium phosphate, diammonium phosphate, triammonium phosphate, ammonium polyphosphate, melanin polyphosphate, resorcinol poly(di-2,6-xylyl)phosphate, and resorcinol polyphenyl phosphate. These flame retardants can be used singly, or in a combination of two or more.

The resin composition according to the present invention may further contain typical resin additives to the extent that the preferable properties of the composition are not impaired. The resin additives can be any resin additives. Examples include UV absorbers (e.g., benzophenone-based UV absorbers, benzotriazole-based UV absorbers, cyanoacrylate-based UV absorbers, triazine-based UV absorbers, and salicylate-based UV absorbers), light stabilizers (e.g., hindered amine-based stabilizers), antioxidants (e.g., hindered phenol-based antioxidants, amine-based antioxidants, copper-based antioxidants, organic phosphorus-based peroxide decomposers, and organic sulfur-based peroxide decomposers), light-shielding agents (e.g., rutile-form titanium oxide, chromium oxide, and cerium oxide), metal deactivators (e.g., benzotriazole-based metal deactivators), quenchers (e.g., organic nickel), natural wax, synthetic wax, higher fatty acids, metal salts of higher fatty acids, anti-fog agents, fungicides, antimicrobial agents, deodorants, plasticizers, antistatic agents, surfactants, polymerization inhibitors, crosslinking agents, dyes, and colorants (e.g., carbon black, titanium oxide, pigments such as colcothar, and dyes), sensitizers, curing accelerators, diluents, fluidity adjusters, antifoaming agents, foaming agents, leveling agents, adhesives, tackifiers, tackiness-imparting agents, unguent, mold-releasing agents, lubricants, solid lubricants (e.g., polyolefin resins such as polytetrafluoroethylene, low-density polyethylene, linear low-density polyethylene, medium-density polyethylene, high-density polyethylene, and ultra-high-molecular weight polyethylene, graphite, molybdenum disulfide, tungsten disulfide, and boron nitride), nucleating agents, reinforcing agents, compatibilizers, conductive materials (e.g., carbon-based conductive materials, metal-based conductive materials, and metal oxide-based conductive materials), anti-blocking agents, anti-tracking agents, phosphorescent agents, and various stabilizers.

### Method for Producing Resin Composition

The resin composition according to the present invention can be produced by weighing a predetermined amount or a suitable amount of the starting materials, and mixing or kneading the starting materials by a known method. For example, the resin composition according to the present invention can be produced by kneading a mixture of the starting materials in the form of powder, beads, flakes, or pellets by using an extruder (e.g., a single-screw extruder or a twin-screw extruder), or a kneader (e.g., a Banbury mixer, a pressure kneader, or a 2-roll or 3-roll kneader). If a liquid needs to be added, the mixture can be kneaded with the extruder or kneader as described above, while using a known liquid injector. The starting materials may be pre-mixed with a mixer (e.g., a tumbler or a Henschel mixer) before use.

The resin composition according to the present invention can also be produced by preparing the flame retardant for resin according to the present invention and a master batch resin composition that optionally contains other additives in a high concentration, and mixing or kneading them optionally with other components.

### Molded Article

The resin composition according to the present invention can be formed into a molded article of any shape, such as single-layered or multiple-layered resin plates, sheets, films, fibers, round bars, square bars, spheres, cubes, pipes, tubes, or other different shapes, by a known molding method, such as cast molding, injection molding, compression molding, transfer molding, insert molding, RIM molding, extrusion molding, inflation molding, and blow molding.

The resin composition according to the present invention has applications in every field in which a resin component is usable. Examples of such fields include electric and electronic equipment, communication equipment, precision equipment, transportation equipment such as automobiles, textile goods, manufacturing machines, food packaging films, containers, agriculture, forestry, fishery, building materials, medical products, and furniture components.

In particular, a molded article formed from the resin composition according to the present invention that contains an epoxy resin as a resin component is preferably used in electric and electronic equipment or communication equipment. Examples of electric and electronic equipment or communication equipment include office automation equipment, such as printers, computers, word processors, keyboards, personal digital assistants (PDA), telephone equipment, mobile devices (e.g., cellular phones, smartphones, and tablets), facsimile equipment, photocopiers, electronic cash registers (ECR), calculators, electronic notebooks, and electronic dictionaries; electric home appliances, such as laundry machines, refrigerators, rice cookers, vacuum cleaners, microwave ovens, lighting equipment, air conditioners, ironing equipment, and kotatsu (Japanese electric heaters); housings of audio-video equipment, such as television sets, tuners, VTRs, video cameras, camcorders, digital still cameras, radio cassette players, tape recorders, MD players, CD players, DVD players, LD players, HDDs (hard disk drives), speakers, car navigation systems, liquid crystal displays, liquid crystal display drivers, EL displays, and plasma displays; materials that partly or entirely constitute mechanical components or structural components; cover resistance, such as electric cables and cables; cases for storing electric elements, such as thermostats and thermal fuses; and materials that partly or entirely constitute sliding components, such as motor bearings, spacers, and wire guides for dot printers.

Of the electric and electronic equipment or communication equipment, the molded article according to the present invention is particularly preferably used in electric or electronic components of electric and electronic equipment or communication equipment, such as sealing materials of semiconductor devices, and substrate materials for wiring boards. The method for sealing a semiconductor device for use can be selected from a wide range of known methods. For example, a semiconductor device such as an active element (e.g., a semiconductor chip, a transistor, a diode, a light-emitting diode (LED), and a thyristor) and a passive element (e.g., a capacitor, a resistor, and a coil) is mounted on a support member such as a lead frame, a pre-wired tape carrier, a wiring board, glass, or silicon wafer; and connected to a pre-formed circuit pattern, followed by sealing some parts with a solution or paste of the resin composition according to the present invention, thereby producing an electronic component.

The mounting method can be any method. For example, methods such as lead frame package, surface mounting package (e.g., SOP: small outline package, SOJ: small outline j-leaded package, QFP: quad flat package, and BGA: ball grid array), and CSP (chip size/scale package) can be used.

The method for connecting a semiconductor device with a circuit pattern can be any method. For example, known methods such as wire bonding, tape automated bonding (TAB) joint, and flip-chip joint can be used.

The most common sealing method is a low-pressure transfer molding. However, sealing methods such as injection molding, compression molding, or casting are also usable. For sealing, the formulation of the resin composition according to the present invention can be suitably changed according to various conditions such as the type of the support member on which an element is mounted, the type of the element to be mounted, the mounting method, the connection method, and the sealing method. The resin composition according to the present invention may also be used as an adhesive in mounting components such as a semiconductor device, solder balls, a lead frame, a heat spreader, and a stiffener on a support member.

Additionally, the resin composition according to the present invention can be formed into a film beforehand, and the film can be used, for example, as a secondary mounting sealing material. Examples of electronic components produced by such a method include tape carrier package (TCP) in which a semiconductor chip connected to a tape carrier with a bump is sealed with the resin composition according to the present invention. Examples also include COB modules, hybrid integrated circuits, and multi-chip modules in which an active element, such as a semiconductor chip, an integrated circuit, a large-scale integrated circuit, a transistor, a diode, and a thyristor, and/or a passive element, such as a capacitor, a resistor, and a coil, are connected to wiring formed on a wiring board or glass by wire bonding, flip chip bonding, solder etc. and sealed with the resin composition according to the present invention.

When the resin composition according to the present invention is used as a substrate material for wiring boards, a conventional method can be used. For example, a base material, such as paper, glass fiber cloth, or aramid fiber cloth, is impregnated with the resin composition according to the present invention, and semi-cured by a method of drying at a temperature of about 90 to 220° C. for about 1 to 5 minutes, thereby forming a prepreg. The prepreg can be used as a substrate material for wiring boards. Alternatively, the resin composition according to the present invention can be formed into a film, and this film can be used as a substrate material for wiring boards. In this case, a functional film, such as a conductive layer, an anisotropic conductive layer, a conductivity control layer, a dielectric layer, an anisotropic dielectric layer, or a permittivity control layer, can be prepared by adding a conductive substance or dielectric substance.

Additionally, the resin composition according to the present invention can also be used as resin-made bumps or a conductive layer that forms inside of through-holes. The resin composition according to the present invention can also be used as an adhesive when a wiring board is prepared by stacking prepregs or films. In this case as well, an inorganic conductive substance, an inorganic dielectric substance, and like substances may be added as in the film formation.

In the present invention, a wiring board may be produced only from a prepreg prepared by impregnating a base material with the resin composition according to the present invention and/or a film formed of the resin composition according to the present invention, or a wiring board may be produced from these prepreg and film in combination with a conventional prepreg and/or film for wiring boards. The wiring board can be any wiring board. For example, the wiring board may be rigid or flexible, and the shape of the wiring board can be suitably selected from a range of, for example, sheets, films, and plates. Examples include metal foil-clad laminates, printed wiring boards, bonding sheets, and resin films with a carrier.

More specifically, examples of metallic foil-clad laminates include copper-clad laminates, composite copper-clad laminates, and flexible copper-clad laminates. These metallic-foil-clad laminates can be prepared in the same manner as a conventional method. For example, metal foil with a thickness of about 2 to 70 μm (e.g., copper and aluminum) is disposed on one or both surfaces of a single prepreg described above or multiple stacked prepregs, and molded into a laminate at a temperature of about 180 to 350° C. and at a surface pressure of about 20 to 100 kg/cm² for a heating time of about 100 to 300 minutes by using a multi-stage press machine, a continuous molding machine, or other machines, thereby preparing a metallic foil-clad laminate.

More specifically, examples of printed wiring boards include build-up multilayer printed wiring boards and flexible printed wiring boards. These printed wiring boards can be prepared in the same manner as a conventional method. For example, the surface of a metallic foil-clad laminate is etched to form an inner-layer circuit, thereby preparing an interior substrate. Several prepregs are then stacked on the surface of the inner-layer circuit, and metallic foil for an outer-layer circuit is laminated on the outer side, followed by heating and applying pressure to integrally mold them, thereby obtaining a multilayer laminate. The obtained multilayer laminate is pierced, and a plated metal film for making conduction between the inner-layer circuit and the metallic foil for the outer-layer circuit is formed on the wall of the hole. The metallic foil for outer-layer circuit is further etched to form an outer-layer circuit, thereby preparing a printed wiring board.

The bonding sheet can be prepared in the same manner as a conventional method. For example, the resin composition according to the present invention is dissolved in a solvent, and the prepared solution is applied to a support material formed of a peelable plastic film, such as a polyethylene film or a polypropylene film, by using a coater such as a roll coater or a comma coater. The applied solution on the support material is heated at about 40 to 160° C. for about 1 to 20 minutes and pressed by a roll or like means, thereby preparing a bonding sheet.

The resin film with a carrier can be prepared in the same manner as a conventional method. For example, the resin composition according to the present invention is dissolved in a solvent, and the obtained solution is applied to a support material formed of a peelable plastic film, such as a polyethylene film or a polypropylene film, by using a bar coater, a doctor blade, or like means, and dried at a temperature of about 80 to 200° C. for about 1 to 180 minutes, thereby preparing a resin film with a carrier.

Other applications include precision equipment, transportation equipment, manufacturing equipment, household goods, and civil engineering and construction materials. Specific examples of precision equipment include materials that partly or entirely constitute the housing, mechanical part, or structural part of, for example, watches, microscopes, and cameras. Specific examples of transportation equipment include materials that partly or entirely constitute the bodies of marine vessels, such as yachts and boats, trains, automobiles, bicycles, motorcycles, and aircraft, and the mechanical components or structural components thereof (e.g., frames, pipes, shafts, convertible tops, door trims, sun visors, wheel covers, hangers, and straps); and materials that partly or entirely constitute the interior components of such transportation equipment (e.g., armrests, package trays, sun visors, and mattress covers). Specific examples of manufacturing equipment include materials that partly or entirely constitute the mechanical or structural components of robot arms, rolls, roll shafts, spacers, insulators, gaskets, thrust washers, gears, bobbins, piston members, cylinder members, pulleys, pump members, bearings, shaft members, leaf springs, honeycomb structure members, masking jigs, distribution boards, and waterproof pans; and materials that partly or entirely constitute industrial tanks such as water tanks, septic tanks, and low tanks, pipes, resin molds, and helmets. Specific examples of household goods include materials that partly or entirely constitute sporting or leisure goods, such as badminton or tennis racket frames, golf club shafts or heads, hockey sticks, ski poles or skis, snowboards, skateboards, fishing rods, bats, and tent posts, bathroom equipment, such as bathtubs, washbasins, toilet bowls, and accessories thereof, sheets, buckets, and hoses; and dressed lumber, such as heat-resistant laminates provided on the surface of furniture top or tables, furniture, and cabinets. Specific examples of civil engineering and construction materials include interior and exterior materials of buildings, roofing materials, flooring materials, wallpaper, window glass, window glass sealing materials, concrete structural buildings (e.g., concrete bridge footing and concrete columns), reinforcing materials for concrete structures (e.g., concrete pillars, walls, and roads), and repair materials for pipelines such as sewage pipes.

### EXAMPLES

The present invention is described in detail with reference to Examples and Comparative Examples. However, the present invention is not limited to these Examples.

### Example 1: Production of Cyclic Phosphazene Compound Represented by Formula (1)

### 1-1. Production of Decachlorocyclopentaphosphazene

Phosphorus pentachloride (0.51 g, 2.4 mmol), ammonium chloride (0.14 g, 2.62 mmol), and monochlorobenzene (5 ml) were placed in an egg-plant flask equipped with a reflux condenser and refluxed for 5 hours. After refluxing, the remaining ammonium chloride was removed by filtration, and the filtrate was concentrated under reduced pressure, followed by drying, thereby obtaining a cyclic chlorophosphazene oligomer containing a trace amount of oil in transparent crystals (0.251 g). The obtained cyclic chlorophosphazene oligomer was subjected to distillation to isolate only decachlorocyclopentaphosphazene, thereby obtaining solid decachlorocyclopentaphosphazene.

### 1-2. Production of 2,2′-Biphenolate

2,2′-Biphenol (491.09 g, 2.62 mol) and chlorobenzene (2.3 L) were placed in a 5 L-flask equipped with a Dean-Stark apparatus and heated with stirring at 60° C. in a nitrogen atmosphere to dissolve 2,2′-biphenol. Thereafter, a 48 mass % aqueous sodium hydroxide solution (446.52 g, 5.30 mol) was added thereto and heated under reflux at 135° C. for 5 hours to allow a reaction to proceed, while water was removed, thereby producing disodium 2,2′-biphenolate.

### 1-3. Production of Cyclic Phosphazene Compound Represented by Formula (1)

The reaction mixture obtained in section 1-2 was cooled to 100° C., and a 27 mass % solution of decachlorocyclopentaphosphazene in chlorobenzene (1064.68 g, 2.5 unit*¹ mol) was added dropwise over a period of 1 hour. The reaction mixture was heated under reflux for 12 hours, and then water was added to partition the reaction mixture. The obtained organic layer was concentrated and dried, and then purified by reverse-phase silica gel column chromatography (developing solvent: acetonitrile), thereby obtaining a solid cyclic phosphazene compound represented by formula (1) (413.88 g).

¹H-NMR (500.13 MHz, CDCl₃, σppm): 7.05-7.59 (multiplet)

³¹P-NMR (202.46 MHz, CDCl₃, σppm): 0.91

MS spectrum data: C₆₀H₄₀N₅O₁₀P₅ (m/z=1146.4: [M+H]⁺), theoretical mass (m/z=1145.15: M⁻)

*1: unit, the minimum structural unit of a cyclic chlorophosphazene compound (PNCl₂)

### Example 2 and Comparative Examples 1 to 4: Preparation of Resin-Molded Article

The individual components were weighed in accordance with the formulations of Table 1, and the components were mixed with heating at 120° C. until the mixture was homogeneous. Thereafter, the mixture was poured into a molding plate with a thickness of 4 mm, and degassed under reduced pressure at 120° C. and at 10 mmHg or less. After degasification, the mixture was heated at 150° C. for 1 hour and at 200° C. for 2 hours to cure it, and the obtained cured product was cooled to room temperature, thereby preparing an epoxy-resin-molded article.

### Flexural Test

Flexural properties were measured in accordance with JIS K7171. The test specimen for use was prepared by processing a molded article prepared in the manner described above into a specimen with a dimension of 80×10×4 mm. The unit is Mpa. Table 1 illustrates the evaluation results.

TABLE 1

| Formulation | | Exam- | Comparative Examples | | | |
|---|---|---|---|---|---|---|
| (part by mass) | | ple 2 | 1 | 2 | 3 | 4 |
| Epoxy | Epoxy Compound*² | 72.9 | 72.9 | 72.9 | 72.9 | 72.9 |
| Resin | Curing Agent*³ | 27.1 | 27.1 | 27.1 | 27.1 | 27.1 |
| | Curing Aid*⁴ | 0.7 | 0.7 | 0.7 | 0.7 | 0.7 |
| Flame | Cyclic Phosphazene | 25.8 | | | | |
| Retardant | Compound*⁵ | | | | | |
| for Resin | Represented by | | | | | |
| | Formula (1) | | | | | |
| | Tridioxybiphenyl | | | 25.8 | | |
| | cyclotriphosphazene*⁶ | | | | | |
| | Phosphoric Acid | | | | 44.5 | |
| | Ester 1*⁷ | | | | | |
| | Phosphoric Acid | | | | | 25.0 |
| | Ester 2*⁸ | | | | | |

| | | | | | |
|---|---|---|---|---|---|
| Average Flexural Strength (Mpa) | 150 | 155 | 84 | 74 | 76 |

*2: Bisphenol F-type epoxy compound: produced by Mitsubishi Chemical Corporation, Epikote 806
*3: Diamino diphenyl sulfone: produced by Tokyo Chemical Industry Co., Ltd.
*4: Triphenylphosphine: produced by Wako Pure Chemical Industries, Ltd.
*5: The compound produced in Example 1
*6: Tridioxybiphenyl cyclotriphosphazene: U.S. Pat. No. 3,356,769
*7: Resorcinol poly(di-2,6-xylyl) phosphate: produced by Daihachi Chemical Industry Co., Ltd., PX-200
*8: Resorcinol polyphenyl phosphate: produced by Adeka Corporation, FP-700

### Flame Retardancy Test

Flame retardancy was measured and evaluated in accordance with UL94. The test specimen was prepared in the manner as described above. The molded articles of Example 2 and Comparative Example 1 were processed into a dimension of 80×10×4 mm and used. Table 2 illustrates the judgement criteria.

TABLE 2

| Judgement Criteria | V-0 | V-1 | V-2 |
|---|---|---|---|
| First after-flame time period | 10 seconds | 30 seconds | 30 seconds |
| of each test specimen | or less | or less | or less |
| Total after-flame time period | 50 seconds | 250 seconds | 250 seconds |
| (5 applications of flame) | or less | or less | or less |
| Second after-flame time | 30 seconds | 60 seconds | 60 seconds |
| period + after-glow time | or less | or less | or less |
| period of each test specimen | | | |
| Combustion up to the holding | No | No | No |
| clamp | | | |
| Ignition of cotton by drips | No | No | Yes |
| of a burning specimen | | | |

As a result of evaluation, the test specimen of Example 2 was classified as V-0, and the test specimen of Comparative Example 1 was completely burned up to the holding clamp.

The results of the flexural test and flame retardancy test indicate that the molded article containing the cyclic phosphazene compound represented by formula (1) exhibits high flame retardancy while maintaining resin-derived mechanical strength.

### INDUSTRIAL APPLICABILITY

The present invention provides a resin composition that has high flame retardancy while maintaining resin-derived mechanical strength, and a molded article of the resin composition.

1: A cyclic phosphazene compound represented by formula (1)

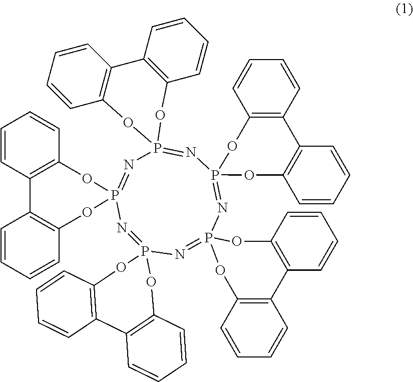 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

2: The resin composition comprising a resin and the cyclic phosphazene compound of claim 1.

3: The resin composition according to claim 2, wherein the cyclic phosphazene compound is present in an amount of 0.01 to 50 parts by mass, per 100 parts by mass of the resin.

4: The resin composition according to claim 2, wherein the resin is at least one member selected from the group consisting of epoxy resin, thermosetting acrylic resin, diallyl phthalate resin, unsaturated polyester resin, styrene-based resin, polyester resin, polycarbonate resin, polyphenylene ether-based resin, and polyamide resin.

5: A molded article prepared by using the resin composition of claim 2.

6: An electric or electronic component prepared by using the resin composition of claim 2.

7: A sealing material for a semiconductor device, the sealing material comprising the resin composition of claim 2.

8: A substrate material prepared by using the resin composition of claim 2.

9: A method for producing a cyclic phosphazene compound represented by formula (1): 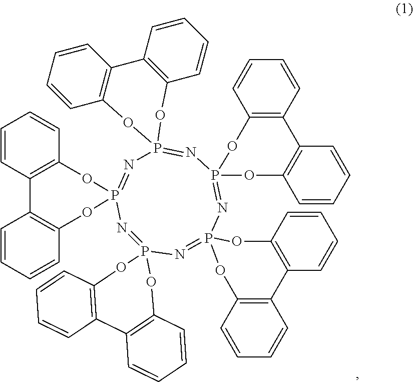 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]
the method comprising reacting decachlorocyclopentaphosphazene with 2,2′-biphenolate.

10: A flame retardant for resin, the flame retardant comprising a cyclic phosphazene compound represented by formula (1)

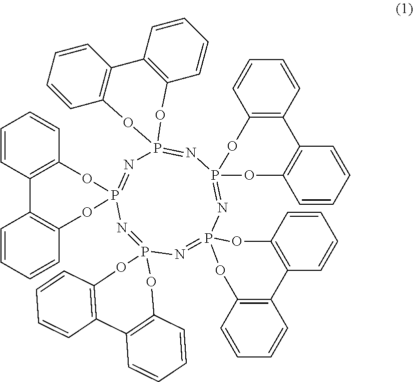 [SMILES: c1ccc2c(c1)OP1(=NP3(=NP4(=NP5(=NP6(=N1)Oc1ccccc1-c1ccccc1O6)Oc1ccccc1-c1ccccc1O5)Oc1ccccc1-c1ccccc1O4)Oc1ccccc1-c1ccccc1O3)Oc1ccccc1-2]

11: The resin composition according to claim 3, wherein the resin is at least one member selected from the group consisting of epoxy resin, thermosetting acrylic resin, diallyl phthalate resin, unsaturated polyester resin, styrene-based resin, polyester resin, polycarbonate resin, polyphenylene ether-based resin, and polyamide resin.

12: A molded article prepared by using the resin composition of claim 3.

13: A molded article prepared by using the resin composition of claim 4.

14: An electric or electronic component prepared by using the resin composition of claim 3.

15: An electric or electronic component prepared by using the resin composition of claim 4.

16: A sealing material for a semiconductor device, the sealing material comprising the resin composition of claim 3.

17: A sealing material for a semiconductor device, the sealing material comprising the resin composition of claim 4.

18: A substrate material prepared by using the resin composition of claim 3.

19: A substrate material prepared by using the resin composition of claim 4.
